(19) United States
(12) Patent Application Publication
(10) Pub. No.: US 2013/0320446 A1
(43) Pub. Date: Dec. 5, 2013

(54) SEMICONDUCTOR STRUCTURE AND METHOD FOR FORMING THE SAME

(71) Applicants: Wei Wang, Beijing (CN); Jing Wang, Beijing (CN); Lei Guo, Beijing (CN)

(72) Inventors: Wei Wang, Beijing (CN); Jing Wang, Beijing (CN); Lei Guo, Beijing (CN)

(21) Appl. No.: 13/576,933

(22) PCT Filed: Jul. 18, 2012
(86) PCT No.: PCT/CN12/78789

§ 371 Date: Aug. 2, 2012

(30) Foreign Application Priority Data
May 30, 2012 (CN) 201210175345.1

(51) Int. Cl. H01L 29/78; H01L 21/336

(52) U.S. Cl. 257/347; 438/151; 257/E29.255; 257/E21.409

(57) ABSTRACT

A semiconductor structure and a method for forming the same are provided. The semiconductor structure comprises: a semiconductor substrate; a rare earth oxide layer formed on the semiconductor substrate; a channel region formed on the rare earth oxide layer; and a source region and a drain region formed at both sides of the channel region respectively, in which a relationship between a lattice constant a of the rare earth oxide layer and a lattice constant b of a semiconductor material of the channel region and/or the source region and the drain region is a=(n±c)b, where n is an integer, c is a mismatch ratio of lattice constants, and 0<c≦15%.

### CROSS-REFERENCE TO RELATED APPLICATION

This application claims priority to and benefits of Chinese Patent Application Serial No. 201210175345.1, filed with the State Intellectual Property Office of P. R. China on May 30, 2012, the entire contents of which are incorporated herein by reference.

### FIELD

The present disclosure relates to semiconductor design and fabrication field, and more particularly to a semiconductor structure and a method for forming the same.

### BACKGROUND

With a development of a semiconductor technology, a feature size of a metal-oxide-semiconductor field-effect transistor (MOSFET) is continuously scaled down. When the feature size reaches a deep submicron or even a nanometer order of magnitude, a series of degeneration effects generally appear, which do not exist or are not obvious when the feature size is a large size, such as a threshold voltage roll-off, a drain induced barrier lowering (DIBL) or an overlarge leakage current.

In order to solve above problems, one solution is that by producing a corresponding stress in a specific region of a semiconductor device according to a type thereof, a carrier mobility of the device may be enhanced, thus improving a performance of the device. In a deep submicron or nanometer device, the suitable stress is important to improve the performance of the device. Conventional methods for producing the stress comprises: adding a substitutional element in a source region and a drain region to change a lattice constant by epitaxial growth or ion implantation, depositing a stress cap layer after forming a device structure, etc. One of the most primary disadvantages of these conventional methods lies in complicated process and difficulty in adjusting stress type. Moreover, with a further scaling down of the feature size of the device, it is difficult to produce an effective stress by the conventional methods, and thus it is hard to significantly improve the performance of the semiconductor device.

### SUMMARY

The present disclosure is aimed to solve at least one of the problems, particularly problems of overlarge leakage current in a device with small size, difficulty in producing a stress, complicated process and unsatisfactory stress effect.

According to an aspect of the present disclosure, a semiconductor structure is provided. The semiconductor structure comprises: a semiconductor substrate; a rare earth oxide layer formed on the semiconductor substrate; a channel region formed on the rare earth oxide layer; and a source region and a drain region formed at both sides of the channel region respectively. A relationship between a lattice constant a of the rare earth oxide layer and a lattice constant b of a semiconductor material of the channel region and/or the source region and the drain region is a=(n±c)b, where n is an integer, c is a mismatch ratio of lattice constants, and 0<c≦15%.

In one embodiment, a thickness of the rare earth oxide layer is not less than 5 nm. To ensure the lattice constant of a surface layer of the rare earth oxide layer not to be affected by the semiconductor substrate and to ensure a larger stress to be induced, the thickness of the rare earth oxide layer may not be too small.

In one embodiment, a material of the rare earth oxide layer comprises any one of (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, (Pr₁₋ₓGdₓ)₂O₃ and a combination thereof, where x is within a range from 0 to 1.

In one embodiment, the rare earth oxide layer is formed by epitaxial growth.

In one embodiment, the source region, the drain region and the channel region are formed by crystal growth, which may help to obtain a high quality crystal.

In one embodiment, the semiconductor material of each of the source region, the drain region and the channel region comprises Si, Ge, SiGe with any Ge content, any group III-V compound semiconductor and any group II-VI compound semiconductor.

In one embodiment, a material of each of the source region and the drain region is a metal. For a CMOS (complementary-metal-oxide-semiconductor) device with a metal source region and a metal drain region, the stress is primarily induced in the channel region by the rare earth oxide layer. By using the metal source region and the metal drain region, a series resistance of the source region and the drain region may be reduced, which may be combined with a stress effect in the channel region to further increase a drive current of the device.

According to another aspect of the present disclosure, a method for forming a semiconductor structure is provided. The method comprises steps of: S01: providing a semiconductor substrate; S02: forming a rare earth oxide layer on the semiconductor substrate; and S03: forming a channel region on the rare earth oxide layer, and forming a source region and a drain region at both sides of the channel region respectively. A relationship between a lattice constant a of the rare earth oxide layer and a lattice constant b of a semiconductor material of the channel region and/or the source region and the drain region is a=(n±c)b, where n is an integer, c is a mismatch ratio of lattice constants, and 0<c≦15%.

In one embodiment, a thickness of the rare earth oxide layer is not less than 5 nm. To ensure the lattice constant of a surface layer of the rare earth oxide layer not to be affected by the semiconductor substrate and to ensure a larger stress to be induced, the thickness of the rare earth oxide layer may not be too small.

In one embodiment, a material of the rare earth oxide layer comprises any one of (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, (Pr₁₋ₓGdₓ)₂O₃ and a combination thereof, where x is within a range from 0 to 1.

In one embodiment, the rare earth oxide layer is formed by epitaxial growth.

In one embodiment, after Step S02, the method further comprises: performing chemical mechanical polishing on a surface of the rare earth oxide layer.

In one embodiment, Step S03 comprises: growing crystals on the rare earth oxide layer to form the channel region, the source region and the drain region respectively. The source region, the drain region and the channel region are formed by crystal growth, which may help to obtain a high quality crystal.

In one embodiment, the semiconductor material of each of the source region, the drain region and the channel region comprises Si, Ge, SiGe with any Ge content, any group III-V compound semiconductor and any group II-VI compound semiconductor.

In one embodiment, Step S03 may comprise steps of: growing crystals on the rare earth oxide layer to form the channel region; and forming a metal source region and a metal drain region on the rare earth oxide layer. For a CMOS (complementary-metal-oxide-semiconductor) device with a metal source region and a metal drain region, the stress is primarily induced in the channel region by the rare earth oxide layer. By using the metal source region and the metal drain region, a series resistance of the source region and the drain region may be reduced, which may be combined with a stress effect in the channel region to further increase a drive current of the device.

With the semiconductor structure and the method for forming the same according to an embodiment of the present disclosure, the rare earth oxide layer is formed under the channel region, the source region and the drain region of the semiconductor device. A lattice constant of a rare earth oxide is about two times as large as that of widely used semiconductor materials such as Si, Ge, and group III-V compound semiconductor materials, which means the crystalline rare earth oxides are lattice coincident on these semiconductor materials. The crystalline rare earth oxides can be epitaxially grown on Si, Ge, and some group III-V compound semiconductor materials. By adjusting an element type and content of the rare earth oxide, the lattice constant thereof may be conveniently adjusted to be slightly larger or smaller than twice that of the material of the source region, the drain region or the channel region, thus producing a stress in the channel region of the semiconductor device during an epitaxial growth process because of a lattice constant difference. Advantages of the present disclosure are listed as follows.

(1) Because the lattice constant of the rare earth oxide is varied with a type and a content of a rare earth element in the rare earth oxide, by adjusting the element type and content of the rare earth oxide, a required stress may be induced in the source and/or the drain and the channel region.

(2) Because the rare earth oxide layer as a stress source of the semiconductor structure is obtained by crystal growth, compared with a conventional stress cap layer or a stress-engineered trench isolation structure, the stress induced in the channel region by the rare earth oxide in the present disclosure is bigger, and a carrier mobility of the device may be more significantly and effectively enhanced.

(3) By using a crystal characteristic of the rare earth oxide, a conventional complicated method for producing a stress may be replaced by crystal epitaxial growth, thus greatly simplifying a process flow.

Additional aspects and advantages of the embodiments of the present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of the disclosure will become apparent and more readily appreciated from the following descriptions taken in conjunction with the drawings in which:

FIG. 1 is a cross-sectional view of a semiconductor structure according to an embodiment of the present disclosure;

FIG. 2 is a flow chart of a method for forming a semiconductor structure according to an embodiment of the present disclosure;

FIGS. 3-4 are cross-sectional views of intermediate statuses of a semiconductor structure formed in steps of a method for forming the semiconductor structure according to an embodiment of the present disclosure.

### DETAILED DESCRIPTION

Embodiments of the present disclosure will be described in detail in the following descriptions, examples of which are shown in the accompanying drawings, in which the same or similar elements and elements having same or similar functions are denoted by like reference numerals throughout the descriptions. The embodiments described herein with reference to the accompanying drawings are explanatory and illustrative, which are used to generally understand the present disclosure. The embodiments shall not be construed to limit the present disclosure.

It is to be understood that phraseology and terminology used herein with reference to device or element orientation (such as, terms like “longitudinal”, “lateral”, “front”, “rear”, “right”, “left”, “lower”, “upper”, “horizontal”, “vertical”, “above”, “below”, “up”, “top”, “bottom” as well as derivative thereof such as “horizontally”, “downwardly”, “upwardly”, etc.) are only used to simplify description of the present invention, and do not alone indicate or imply that the device or element referred to must have or operated in a particular orientation.

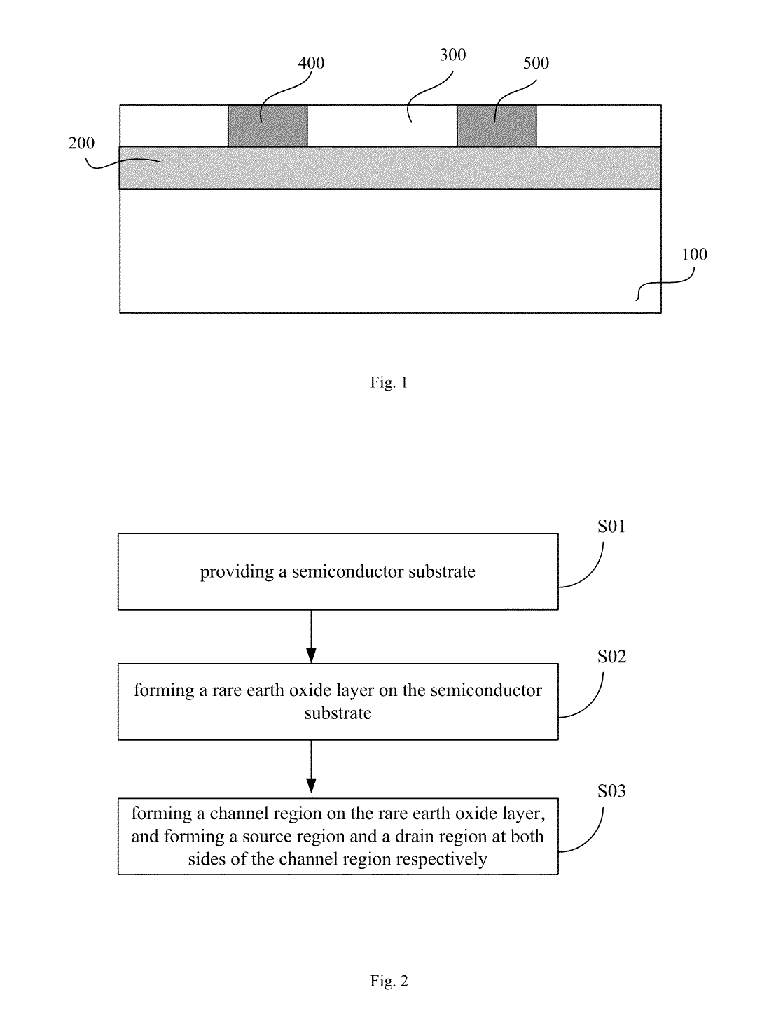

FIG. 1 is a cross-sectional view of a semiconductor structure according to an embodiment of the present disclosure. As shown in FIG. 1, the semiconductor structure comprises: a semiconductor substrate 100; a rare earth oxide layer 200 formed on the semiconductor substrate 100; a channel region 300 formed on the rare earth oxide layer 200; and a source region 400 and a drain region 500 formed at both sides of the channel region 300 respectively.

In one embodiment, a material of the semiconductor substrate 100 comprises single crystal Si (silicon), single crystal Ge (germanium), SiGe (silicon-germanium) with any Ge content, any group III-V compound semiconductor, SOI (silicon-on-insulator), GeOI (germanium-on-insulator) or other semiconductor substrate materials.

To ensure the lattice constant of a surface layer of the rare earth oxide layer 200 not to be affected by the semiconductor substrate 100 and to ensure a larger stress to be induced, a thickness of the rare earth oxide layer 200 may not be too small. In one embodiment, the thickness of the rare earth oxide layer 200 may be not less than 5 nm. When a difference between a lattice constant of the rare earth oxide layer 200 and an integral multiple of a lattice constant of a material of the channel region 300 is bigger, that is, a mismatch ratio of lattice constants is bigger, such as 10-15%, a thinner rare earth oxide layer may induce enough stress in the channel region 300. However, when the mismatch ratio of lattice constants is smaller, such as 0.1-1%, a thicker rare earth oxide layer is needed to induce enough stress in the channel region 300.

In some embodiments, stresses are induced in the channel region, the source region and the drain region by forming the rare earth oxide layer under the channel region, the source region and the drain region. In one embodiment, a material of the rare earth oxide layer 200 may comprise various rare earth oxides and a combination thereof, such as any one of (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, (Pr₁₋ₓGdₓ)₂O₃ and a combination thereof, where x is within a range from 0 to 1. Specifically, the material of the rare earth oxide layer 200 may comprise Er₂O₃, Gd₂O₃, Nd₂O₃, Pr₂O₃, La₂O₃, etc. Because the lattice constant of the rare earth oxide is varied with a type and a content of a rare earth element in the rare earth oxide, by adjusting the element type and the content of the rare earth oxide, the lattice constant of the rare earth oxide layer 200 under both the source region 400 and the drain region 500 may be adjusted to be matched with the lattice constant of the material of the source region 400 and/or the drain region 500 and/or the channel region 300, thus producing a tunable stress in the source region 400 and/or the drain region 500 and the channel region 300. In some embodiments, so called “match” means that a relationship between a lattice constant a of the rare earth oxide layer 200 and a lattice constant b of a semiconductor material of the source region 400 and the drain region 500 and/or the channel region 300 is a=(n±c)b, where n is an integer, c is a mismatch ratio of lattice constants, and 0<c≦15%. For example, in one embodiment, the material of each of the source region 400, the drain region 500 and the channel region 300 may be Si or Ge, and by adjusting the constituent of the rare earth oxide, the lattice constant of the rare earth oxide layer 200 may be adjusted to be slightly larger or smaller than twice that of Si or Ge. If a is just an integral multiple of b, a stress may not be induced in the source region 400 and the drain region 500; if a is slightly larger than the integral multiple of b, a stress may be induced in the source region 400 and the drain region 500, and may be presented as a tensile stress in the channel region 300 via transmission, thus raising an electron mobility in the channel region 300; and if a is slightly smaller than the integral multiple of b, a stress may be induced in the source region 400 and the drain region 500, and may be presented as a compressive stress in the channel region 300 via transmission, thus raising a hole mobility in the channel region 300. Generally, the mismatch ratio of lattice constants is within 15%.

In a preferred embodiment, the rare earth oxide layer 200 is formed by epitaxial growth, such as an ultra-high vacuum chemical vapor deposition (UHVCVD), an atomic layer deposition (ALD), a metal-organic chemical vapor deposition (MOCVD) or a molecular beam epitaxy (MBE). Because the rare earth oxide layer 200 as a stress source is obtained by crystal growth, compared with a conventional stress cap layer or a stress-engineered trench isolation structure, the stress induced in the channel region by the rare earth oxide in the present disclosure is bigger, and a carrier mobility of the device may be more significantly and effectively enhanced.

In this embodiment, a material of each of the source region 400, the drain region 500 and the channel region 300 may comprise single crystal Si, single crystal Ge, SiGe with any Ge content, any group III-V compound semiconductor and any group II-VI compound semiconductor. Preferably, the source region 400, the drain region 500 and the channel region 300 may be all formed by crystal growth, which may help to obtain a high quality crystal. It should be noted that thicknesses of the source region 400, the drain region 500 and the channel region 300 may not be overlarge, or else the stress in the channel region 300 induced by the rare earth oxide layer 200 will be released and it will not help to form a source and a drain with low resistance so as to cause a poor performance of the device. It should be noted that particular structures of the source/drain region and the channel region are not limited in the present disclosure, and any structures of the source/drain region and the channel region existing in the art or to be developed in future may be within the scope of the present disclosure.

In an alternative embodiment, a material of each of the source region 400 and the drain region 500 may also be a metal, which may include, but are not limited to, Al, Cu, Pt, Ni, W, Er, Ti, Yb, other metals, rare earth metals, or a combination thereof. For a CMOS device having a metal source and a metal drain, the stress is primarily induced in the channel region 300 by the rare earth oxide layer 200. By using the metal source region and the metal drain region, a series resistance of the source region and the drain region may be reduced, which may be combined with a stress effect in the channel region to further increase a drive current of the device.

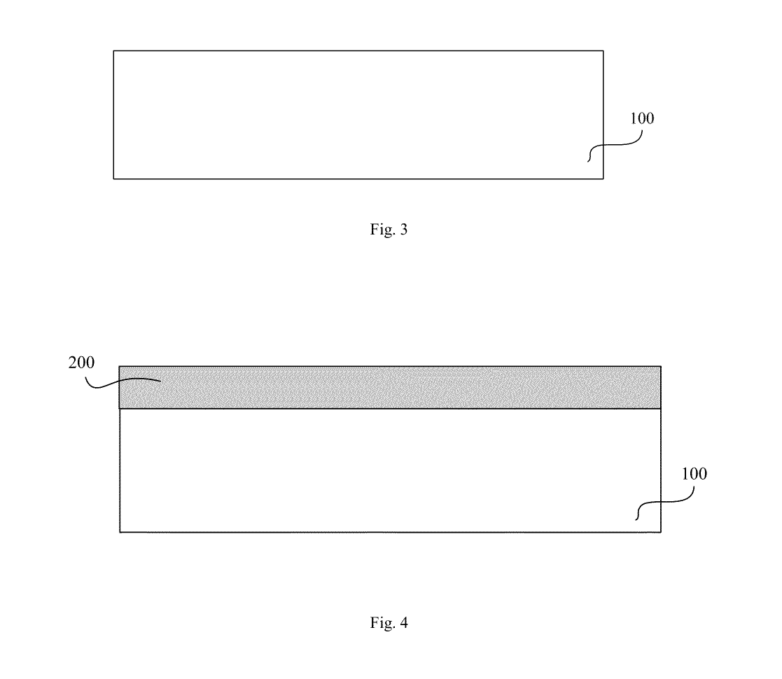

According to another aspect of the present disclosure, a method for forming the above semiconductor structure is provided. FIG. 2 is a flow chart of a method for forming a semiconductor structure according to an embodiment of the present disclosure. FIGS. 3-4 are cross-sectional views of intermediate statuses of a semiconductor structure formed in steps of a method for forming the semiconductor structure according to an embodiment of the present disclosure. The method comprises following steps.

Step S01: a semiconductor substrate 100 is provided, as shown in FIG. 3. In one embodiment, a material of the semiconductor substrate 100 may comprise single crystal Si, single crystal Ge, SiGe with any Ge content, any group III-V compound semiconductor, SOI, GeOI or other semiconductor substrate materials.

Step S02: a rare earth oxide layer 200 is formed on the semiconductor substrate 100, as shown in FIG. 4. In one embodiment, a material of the rare earth oxide layer 200 may comprise various rare earth oxides and a combination thereof, such as any one of (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, (Pr₁₋ₓGdₓ)₂O₃ and a combination thereof, where x is within a range from 0 to 1. In a preferred embodiment, the rare earth oxide layer 200 is formed by epitaxial growth, such as UHVCVD, ALD, MOCVD or MBE. Because a stress source of the semiconductor structure is obtained by crystal growth, compared with a conventional stress cap layer or a stress-engineered trench isolation structure, the stress induced in the channel region by the rare earth oxide in the present disclosure is bigger, and a carrier mobility of the device may be more significantly and effectively enhanced. To ensure the lattice constant of a surface layer of the rare earth oxide layer 200 not to be affected by the semiconductor substrate 100 and to ensure a larger stress to be induced, a thickness of the rare earth oxide layer 200 may not be too small. In one embodiment, the thickness of the rare earth oxide layer 200 may be not less than 5 nm. In an alternative embodiment, after the rare earth oxide layer 200 is formed, a device surface may be polished to obtain a flat surface, for example, by a chemical mechanical polishing (CMP).

Step S03: a channel region 300 is formed on the rare earth oxide layer 200, and a source region 400 and a drain region 500 are formed at both sides of the channel region 300 respectively, as shown in FIG. 1. In some embodiments, a material of each of the source region 400, the drain region 500 and the channel region 300 may comprise single crystal Si, single crystal Ge, SiGe with any Ge content, any group III-V compound semiconductor and any group II-VI compound semiconductor. Preferably, the source region 400, the drain region 500 and the channel region 300 may be all formed by crystal growth, which may help to obtain a high quality crystal. It should be noted that thicknesses of the source region 400, the drain region 500 and the channel region 300 may not be overlarge, or else the stress in the channel region 300 induced by the rare earth oxide layer 200 will be released and it will not help to form a source and a drain with low resistance so as to cause a poor performance of the device. In addition, it should be noted that structures and forming processes of the source/drain region and the channel region are not limited in the present disclosure, and any process existing in the art or to be developed in future may be used to form the source/drain region and the channel region.

Because the lattice constant of the rare earth oxide is varied with a type and a content of a rare earth element in the rare earth oxide, by adjusting the element type and content of the rare earth oxide, the lattice constant of the material of the rare earth oxide layer 200 under the source region 400 and the drain region 500 may be adjusted to be matched with the lattice constant of the material of the source region 400, the drain region 500 and the channel region 300, that is, the lattice constant of the material of the rare earth oxide layer 200 may be adjusted to be slightly larger or smaller than twice that of the material of the source region 400, the drain region 500 or the channel region 300, thus producing a tunable stress in the source region 400, the drain region 500 and the channel region 300 because of a lattice constant difference.

Alternatively, Step S03 may comprise: growing crystals on the rare earth oxide layer 200 to form the channel region 300; and forming a metal source region 400 and a metal drain region 500 on the rare earth oxide layer 200 respectively. For a CMOS device with a metal source region and a metal drain region, the stress is primarily induced in the channel region by the rare earth oxide layer. By using the metal source region and the metal drain region, a series resistance of the source region and the drain region may be reduced, which may be combined with a stress effect in the channel region to further increase a drive current of the device.

In one embodiment, a method for forming the semiconductor structure herein above by a MOCVD process will be described below in detail.

Step S101: a semiconductor substrate is provided. In one embodiment, a material of the semiconductor substrate may be Si with a preferred orientation of <110> or <111>.

Step S102: a rare earth oxide layer is formed on the semiconductor substrate by MOCVD. For example, for a NMOS device, with Nd(thd)₃ (tris (2,2,6,6-tetramethyl-3,5-heptanedionato) neodymium) as a metal precursor and with O₂ as an oxygen source, the rare earth oxide Nd₂O₃ layer with a thickness of 30 nm is obtained by MOCVD at a temperature of 850° C.

Step S103: a channel region material is grown on the rare earth oxide layer. Because a lattice constant of the rare earth oxide Nd₂O₃ is slightly bigger than twice that of Si, a tensile stress may be induced in the channel region, thus enhancing an electron mobility in the channel region. After the channel region are formed, subsequent processes are performed, for example, a metal source region and a metal drain region are deposited, a gate stack and a side wall are formed, the source region and the drain region are implanted and activated, and contacts are formed. A transistor having a rare earth oxide layer under the channel region, the source region and the drain region is finally formed.

With the semiconductor structure and the method for forming the same according to embodiments of the present disclosure, the rare earth oxide layer is formed under the channel region, the source region and the drain region. By adjusting the element type and content of the rare earth oxide layer, the lattice constant of the rare earth oxide layer may be adjusted. Because of lattice constant differences between the rare earth oxide layer and the channel region, between the rare earth oxide layer and the source region and/or between the rare earth oxide layer and the drain region, a tunable stress is induced in the channel region of the semiconductor device during the epitaxial growth process, thus significantly improving the carrier mobility of the semiconductor device. Moreover, by using a crystal characteristic of the rare earth oxide, a conventional complicated method for producing a stress may be replaced by crystal growth, thus greatly simplifying a process flow.

Reference throughout this specification to “an embodiment”, “some embodiments”, “one embodiment”, “an example”, “a specific example”, or “some examples” means that a particular feature, structure, material, or characteristic described in connection with the embodiment or example is included in at least one embodiment or example of the disclosure. Thus, the appearances of the phrases such as “in some embodiments”, “in one embodiment”, “in an embodiment”, “in an example”, “in a specific example”, or “in some examples” in various places throughout this specification are not necessarily referring to the same embodiment or example of the disclosure. Furthermore, the particular features, structures, materials, or characteristics may be combined in any suitable manner in one or more embodiments or examples.

Although explanatory embodiments have been shown and described, it would be appreciated by those skilled in the art that changes, alternatives, and modifications may be made in the embodiments without departing from spirit and principles of the disclosure. Such changes, alternatives, and modifications all fall into the scope of the claims and their equivalents.

1. A semiconductor structure, comprising:
a semiconductor substrate;
a rare earth oxide layer formed on the semiconductor substrate;
a channel region formed on the rare earth oxide layer; and
a source region and a drain region formed at both sides of the channel region respectively,
wherein a relationship between a lattice constant a of the rare earth oxide layer and a lattice constant b of a semiconductor material of the channel region and/or the source region and the drain region is a=(n±c)b, where n is an integer, c is a mismatch ratio of lattice constants, and 0<c≦15%.

2. The semiconductor structure according to claim 1, wherein a thickness of the rare earth oxide layer is not less than 5 nm.

3. The semiconductor structure according to claim 1, wherein a material of the rare earth oxide layer comprises any one of (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, (Pr₁₋ₓGdₓ)₂O₃ and a combination thereof, where x is within a range from 0 to 1.

4. The semiconductor structure according to claim 1, wherein the rare earth oxide layer is formed by epitaxial growth.

5. The semiconductor structure according to claim 1, wherein the source region, the drain region and the channel region are formed by crystal growth.

6. The semiconductor structure according to claim 1, wherein the semiconductor material of each of the source region, the drain region and the channel region comprises Si, Ge, SiGe with any Ge content, any group III-V compound semiconductor and any group II-VI compound semiconductor.

7. A method for forming a semiconductor structure, comprising steps of:
S01: providing a semiconductor substrate;
S02: forming a rare earth oxide layer on the semiconductor substrate; and
S03: forming a channel region on the rare earth oxide layer, and forming a source region and a drain region at both sides of the channel region respectively,
wherein a relationship between a lattice constant a of the rare earth oxide layer and a lattice constant b of a semiconductor material of the channel region and/or the source region and the drain region is a=(n±c)b, where n is an integer, c is a mismatch ratio of lattice constants, and 0<c≦15%.

8. The method according to claim 7, wherein a thickness of the rare earth oxide layer is not less than 5 nm.

9. The method according to claim 7, wherein a material of the rare earth oxide layer comprises any one of (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, (Pr₁₋ₓGdₓ)₂O₃ and a combination thereof, where x is within a range from 0 to 1.

10. The method according to claim 7, wherein the rare earth oxide layer is formed by epitaxial growth.

11. The method according to claim 7, after Step S02, further comprising: performing chemical mechanical polishing on a surface of the rare earth oxide layer.

12. The method according to claim 7, wherein Step S03 comprises: growing crystals on the rare earth oxide layer to form the channel region, the source region and the drain region respectively.

13. The method according to claim 12, wherein the semiconductor material of each of the source region, the drain region and the channel region comprises Si, Ge, SiGe with any Ge content, any group III-V compound semiconductor and any group II-VI compound semiconductor.
